(19) United States
(12) Patent Application Publication
(10) Pub. No.: US 2025/0105119 A1
(43) Pub. Date: Mar. 27, 2025

(54) SELF-HEALING LINER FOR THROUGH GLASS VIA RELIABILITY

(71) Applicant: Intel Corporation, Santa Clara, CA (US)

(72) Inventors: Yuqin LI, Chandler, AZ (US); Jesse JONES, Chandler, AZ (US); Sandrine LTEIF, Phoenix, AZ (US); Srinivas V. PIETAMBARAM, Chandler, AZ (US); Suresh Tanaji NARUTE, Chandler, AZ (US); Pramod MALATKAR, Chandler, AZ (US); Gang DUAN, Chandler, AZ (US); Khaled AHMED, San Jose, CA (US)

(21) Appl. No.: 18/373,848

(22) Filed: Sep. 27, 2023

(51) Int. Cl. H01L 23/498; H01L 21/48; H01L 23/00; H01L 23/15

(52) U.S. Cl. CPC H01L 23/49827; H01L 21/481; H01L 21/486; H01L 23/49894; H01L 23/15; H01L 24/16; H01L 2224/16225

(57) ABSTRACT

Embodiments disclosed herein include glass cores with vias that are lined by a self-healing liner. In an embodiment, an apparatus comprises a substrate that comprises a solid glass layer with an opening through a thickness of the substrate. In an embodiment, a liner is in contact with a sidewall of the opening, where the liner comprises a polymer matrix with capsules distributed through the polymer matrix. In an embodiment, each capsule comprises a shell, and a core within the shell. In an embodiment, the core comprises an organic material. In an embodiment, a via is in the opening and in contact with the liner, and the via is electrically conductive.

### BACKGROUND

As semiconductor packaging architectures continue towards more complex and more compact systems, new material solutions may be used to enable such architectures. One promising candidate for use in packaging substrates is a glass core layer. In such substrates, a glass core is sandwiched between overlying and underlying buildup layers. Electrically conductive vias are provided through the glass core in order to provide electrical coupling between the overlying and underlying buildup layers. Glass cores are beneficial because they can provide high density vias. Glass is also s high modulus material, which provides desirable stiffness to the overall package substrate.

However, glass cores are not without issue. For example, the electrically conductive material for the via (e.g., copper or a copper alloy) has a different coefficient of thermal expansion (CTE) than the glass core. During reflow processes, annealing processes, or any other temperature cycling, the via expands more than the glass core. This induces significant stress into the glass core and can result in cracking or other damage. In some instances, the damage is significant and can lead to complete device failure.

### BRIEF DESCRIPTION OF THE DRAWINGS

FIG. 1A is a cross-sectional illustration of a glass layer with a via and a liner, in accordance with an embodiment.

FIG. 1B is a cross-sectional illustration of a glass layer with a via and a liner, and where a crack has formed at the interface between the glass layer and the liner, in accordance with an embodiment.

FIG. 1C is a cross-sectional illustration of the glass layer after the crack has been filled with a cured polymer, in accordance with an embodiment.

FIG. 2 is a cross-sectional illustration of a capsule that can be distributed within the liner to provide self-healing properties to the liner and the glass layer, in accordance with an embodiment.

FIG. 3A is a cross-sectional illustration of a glass layer with a liner that is filled with composite capsules for self-healing, in accordance with an embodiment.

FIG. 3B is a cross-sectional illustration of the glass layer after a crack has formed at the interface between the glass layer and the liner, in accordance with an embodiment.

FIG. 3C is a cross-sectional illustration of the glass layer after the capsules in the liner are cracked to release the organic liquid, in accordance with an embodiment.

FIG. 3D is a cross-sectional illustration of the glass layer after the liquid has filled the crack and the liquid is cured, in accordance with an embodiment.

FIG. 4A is a cross-sectional illustration of a glass layer with a liner that is filled with nanoparticles and a crack is in the liner, in accordance with an embodiment.

FIG. 4B is a cross-sectional illustration of the glass layer with the nanoparticles conglomerating around the crack in the liner to melt and reform the liner, in accordance with an embodiment.

FIG. 5A is a cross-sectional illustration of a glass layer with a liner that is filled with nanoparticles, and a crack is in the glass layer, in accordance with an embodiment.

FIG. 5B is a cross-sectional illustration of the glass layer with the nanoparticles conglomerating around the crack in the glass to melt and reform the glass layer, in accordance with an embodiment.

FIG. 6 is a cross-sectional illustration of a glass layer with an embedded conductive loop to provide a magnetic field in the liner to activate the nanoparticles for self-healing applications, in accordance with an embodiment.

FIGS. 7A-7F are cross-sectional illustrations depicting a process for forming a via with a self-healing liner that passes through a glass layer, in accordance with an embodiment.

FIG. 8 is a cross-sectional illustration of an electronic system that includes a package substrate with a glass core and vias that employ self-healing liners, in accordance with an embodiment.

FIG. 9 is a schematic of a computing device built in accordance with an embodiment.

### EMBODIMENTS OF THE PRESENT DISCLOSURE

Described herein are electronic systems, and more particularly, liners for through glass vias (TGVs) that provide self-healing for one or both of the liner and the adjacent glass, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

As noted above, glass core architectures are of growing interest in the semiconductor packaging industry. Glass substrates provide improved mechanical performance and allow for higher density via formation. However, one challenge that has arisen from the use of glass substrates is the coefficient of thermal expansion (CTE) mismatch between the glass material and the electrically conductive via. For example, the CTE of many suitable glass materials is typically approximately 5 parts per million/° C. (ppm/° C.) or less, whereas the CTE of copper is around 16 ppm/° C.

One solution that has been proposed to mitigate the CTE mismatch has been to include a compliant liner between the via and the glass layer. Typically, the liner is a low modulus material. For example, proposed liner materials may include organic materials, such as polymers, organo-metallic materials, and the like. Despite the presence of the liners, cracks and other defects can still be generated in the glass or even in the liner itself. Accordingly, additional solutions are desired in order to mitigate these defects.

Embodiments disclosed herein enable a self-healing solution for defects in and around the via in glass substrates. As used, herein, “self-healing” may refer to a process of repairing defects within the structure using components that are pre-existing in the structure. In some applications, “self-healing” may also rely (at least partially) on the external application of thermal energy (e.g., heat) or the external application of a magnetic field. Though, the external application of energy is not necessary in all self-healing applications.

Particularly, embodiments disclosed herein include at least two classes of different self-healing approaches. A first approach involves the presence of self-healing capsules. The capsules can be distributed throughout the liner between the via and the glass. The capsules may include a solid shell that is filled with an organic liquid. Upon application of sufficient pressure, the shell fractures to release the liquid. The liquid can then flow to the defect and ultimately be solidified by curing. A second approach involves the presence of self-healing nanoparticles. The nanoparticles may be paramagnetic. As such, the application of a magnetic field can result in rapid vibrations that can melt materials (e.g., the liner matrix or the glass) in order to cure defects.

The structures disclosed herein are generally described as being glass cores for package substrates. In such instances, the glass layer may have a geometry and dimensions suitable for use as a core between two opposing organic layers. For example, a glass core may have a thickness between approximately 100 μm and approximately 2,000 μm. Though, larger or smaller cores may also be used. As used herein, “approximately” may refer to a range of values within ten percent of the stated value. For example, approximately 100 μm may refer to a range between 90 μm and 110 μm.

However, it is to be appreciated that embodiments disclosed herein are not solely limited to cored package substrate applications. That is, other form factors and applications (e.g., glass interposers, etc.) may also benefit from self-healing solutions in order to mitigate defects generated by CTE mismatch between glass and a metallic via through the glass.

As used in embodiments disclosed herein, glass layers may be substantially all glass. The glass layer may be a solid material with an amorphous crystal structure. More particularly, the glass layer may be any suitable glass formulation that has the necessary mechanical robustness and compatibility with semiconductor packaging manufacturing and assembly processes. For example, the glass layer may comprise aluminosilicate glass, borosilicate glass, alumino-borosilicate glass, silica, fused silica, or the like. In some embodiments, the glass layer may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, and Zn. More generally, the glass layer may comprise silicon and oxygen, as well as any one or more of aluminum, boron, magnesium, calcium, barium, tin, sodium, potassium, strontium, phosphorus, zirconium, lithium, titanium, and zinc. In an embodiment, the glass layer may comprise at least 23 percent silicon (by weight) and at least 26 percent oxygen (by weight). In some embodiments, the glass layer may further comprise at least 5 percent aluminum (by weight).

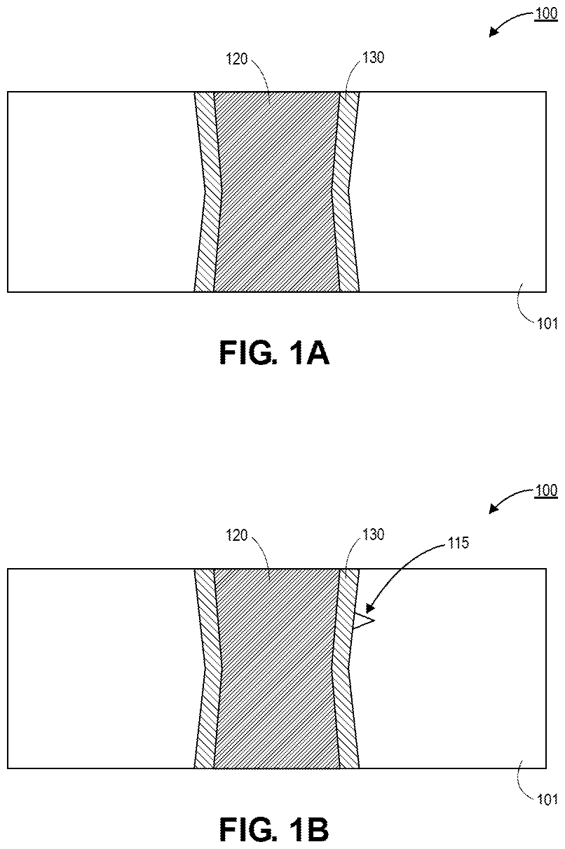

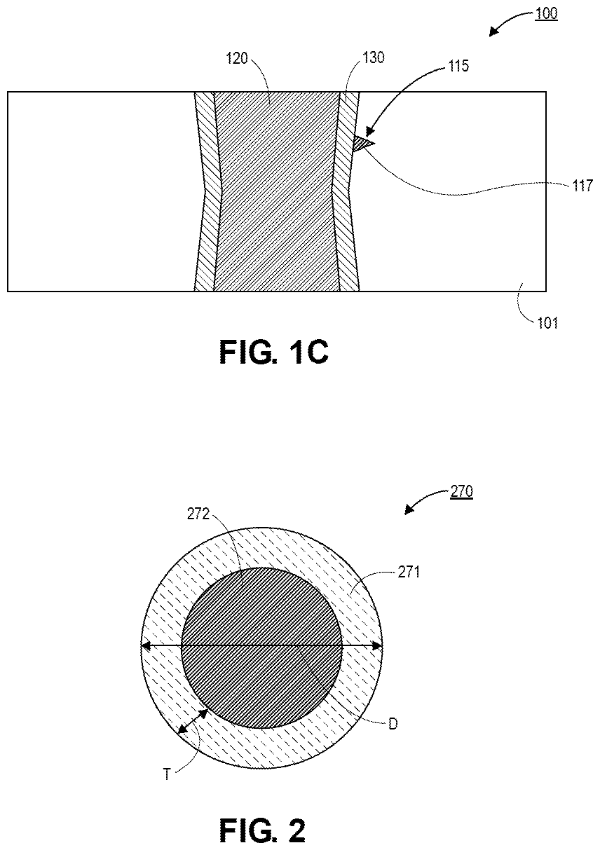

Referring now to FIG. 1A, a cross-sectional illustration of a substrate 100 is shown, in accordance with an embodiment. The substrate 100 may comprise a glass layer 101. The glass layer 101 may be a solid glass material. For example, the glass layer 101 may have a structure and/or material composition similar to any of the glass layer formulations described in greater detail herein. In one embodiment, the substrate 100 may be configured for use as a core in a package substrate.

In an embodiment, a via 120 is provided through a thickness of the glass layer 101. The via 120 is an electrically conductive material. For example, the via 120 may comprise copper, copper and any suitable alloying element, silver, aluminum, or any other electrically conductive material. Further, while shown as a single continuous layer, the via 120 may be formed by multiple layers. For example, a seed layer (not shown) may be used in order to plate the remainder of the via 120. In an embodiment the via 120 may have a minimum diameter that is approximately 15 μm or larger. In some embodiments, the via 120 may have a minimum diameter that is between approximately 25 μm and approximately 200 μm. Though, smaller or larger diameters may also be used for the via 120.

In an embodiment, the via 120 may have sidewalls with any suitable profile. In the example shown in FIG. 1A, the via 120 has a double tapered sidewall profile. This may result in the via 120 having an hourglass-shaped cross section. Though, embodiments may include a via 120 with a single taper or even substantially vertical sidewalls. The sidewall profiles of the via 120 are generally dictated by the processing operations used to manufacture the openings through the glass layer 101.

In an embodiment, the via 120 may be spaced away from the glass layer 101 by a liner 130. The liner 130 may be a compliant material that is used to decouple the expansion of the via 120 from the expansion of the glass layer 101. The liner 130 may be a low modulus polymer or the like. The liner 130 may have any suitable thickness. For example, the thickness of the liner 130 may be between approximately 1 μm and approximately 30 μm. Though thinner or thicker liners 130 may also be used in some embodiments.

In the illustrated embodiment, the liner 130 is shown as a single monolithic structure. As will be described in greater detail below, embodiments are not limited to a single material structure. Instead, embodiments may include a self-healing component that is integrated into the liner 130. For example, composite capsules may be used in some embodiments, and other embodiments may include superparamagnetic nanoparticles.

Referring now to FIG. 1B, a cross-sectional illustration of the substrate 100 after a defect 115 has formed is shown, in accordance with an embodiment. In an embodiment, the defect 115 may be a crack, a micro-crack, a void, or any other type of defect. As noted above, defects 115 may be the result of CTE mismatches between the glass layer 101 and the via 120. Even when a liner 130 is used, the forces applied by the expanding via 120 may be such that cracks are initiated and/or propagated. The illustration shown in FIG. 1B is a defect 115 that is a crack that opens towards the liner 130 and comes to a point within the glass layer 101. The defect 115 in FIG. 1B is simplified for ease of illustration. In reality, cracks and the like may have complex shapes with multiple turns, branches, and other structures.

In some embodiments, the defect 115 may be considered as being at (or near) the interface between the glass layer 101 and the liner 130. In an embodiment, the defect 115 is entirely within the glass layer 101. In another embodiment, the defect 115 may be entirely within the liner 130. Embodiments may also include defects 115 that are within the liner 130 and the glass layer 101. Further, while a single defect 115 is shown in FIG. 1B, it is to be appreciated that two or more defects 115 may be present within the glass layer 101 and/or the liner 130.

Referring now to FIG. 1C, a cross-sectional illustration of the substrate 100 after the defect 115 has been mitigated is shown, in accordance with an embodiment. The defect 115 may be mitigated with a self-healing process. That is, one or more components within the substrate 100 may be used in order to mitigate the presence of the defect 115. For example, and as will be described in greater detail below, the liner 130 may include different filler components (not shown in FIG. 1C) that can fix the defect 115. In one instance, composite capsules with a solid shell and a curable liquid core are used to heal the defect 115. In another instance, superparamagnetic nanoparticles that can induce melting are used to heal the defect 115.

In the illustrated embodiment, the defect 115 is filled by a filler 117. The filler 117 can be a cured and/or cross-linked polymer. That is, a solid material is inserted into the defect 115. This can reduce the stress at the high energy points of the defect 115, which can mitigate or prevent further propagation of the defect 115 deeper into the glass layer 101. In other embodiments, portions of the glass layer 101 are melted in order to reform a solid and substantially uniform region of glass material, essentially erasing the defect 115. As such, there is no further risk of defect 115 propagation.

Referring now to FIG. 2, a cross-sectional illustration of a capsule 270 that can be used in a self-healing liner architecture is shown, in accordance with an embodiment. In an embodiment, the capsule 270 may comprise a solid shell 271 and a core 272. The core 272 may be a liquid core 272, or a partially liquid core 272. The core 272 may remain substantially liquid at temperatures between approximately 0° C. and approximately 50° C., or at temperatures between approximately 25° C. and approximately 75° C. The core 272 may be an organic core, such as a low molecular weight polymer. In other embodiments, the core 272 may comprise an uncured organic monomer and/or an uncured organic oligomer. The core 272 may also comprise a solvent and/or a cross-linking agent. In an embodiment, the shell 271 may be an inorganic material. In one embodiment, the shell 271 comprises silicon and oxygen (e.g., SiO₂).

The capsule 270 may have any suitable dimensions compatible with integration into the matrix of the liner material. For example, the diameter D of the capsule 270 may be between approximately 500 nm and approximately 5,000 nm. Though, smaller diameters D and larger diameters D may also be used in some embodiments. The thickness T of the shell 271 may also be controllable. Larger thicknesses T will result in a capsule 270 that is harder to crack. In an embodiment, the thickness T of the shell 271 may be between approximately 10 nm and approximately 100 nm. Though larger or smaller thicknesses T may be used in alternative embodiments.

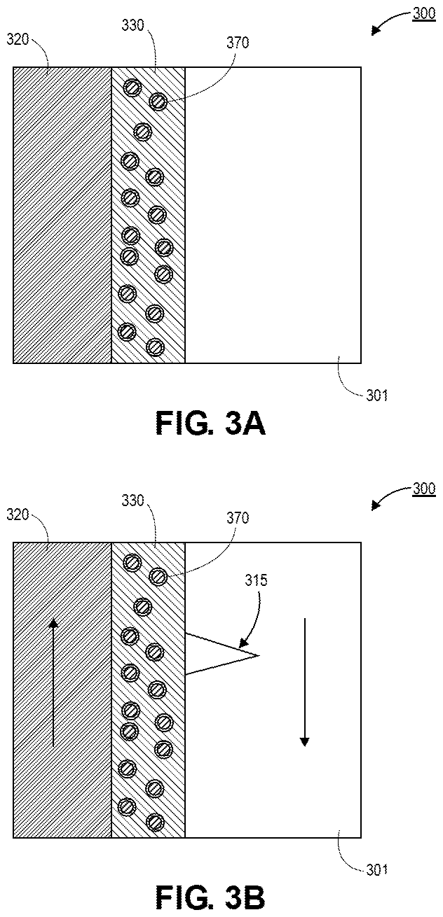

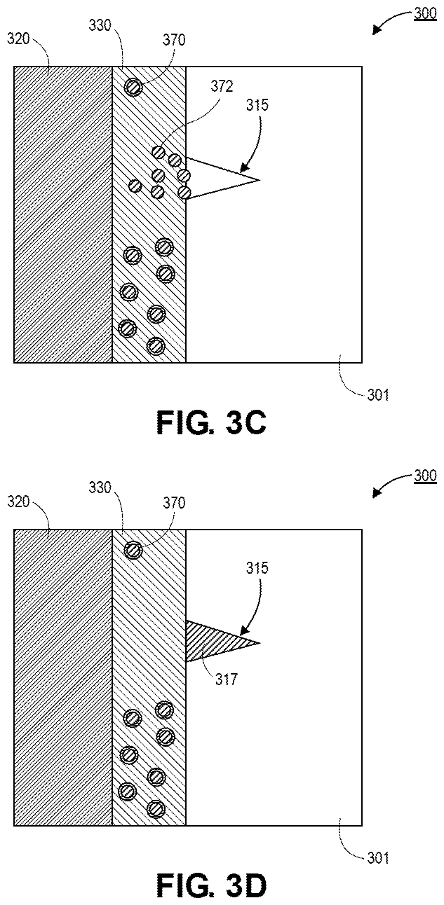

Referring now to FIGS. 3A-3D, a series of cross-sectional illustrations depicting a process for fixing a defect 315 in a substrate 300 with a self-healing process is shown, in accordance with an embodiment.

Referring now to FIG. 3A, a cross-sectional illustration of a substrate 300 is shown, in accordance with an embodiment. In an embodiment, the substrate 300 comprises a glass layer 301. The glass layer 301 may be similar in material composition and geometry to any of the glass layers described in greater detail herein. In an embodiment, a via 320 is provided through a thickness of the glass layer 301. The via 320 may be an electrically conductive material, such as copper, an alloy of copper, or any other suitable metallic material. The via 320 may be separated from the glass layer 301 by a liner 330. In the illustrated embodiment, only a zoomed in illustration of a single interface between the via 320, liner 330, and glass layer 301 is shown for simplicity. However, it is to be appreciated that the substrate 300 may have via 320 and liner 330 structures that are similar to those described above with respect to FIGS. 1A-1C.

In an embodiment, the liner 330 may comprise a matrix material and a filler material. The matrix material may be a low modulus polymer or any other suitable compliant material. The filler material may be composite capsules 370. The capsules 370 may include a solid outer shell with a liquid (or at least partially liquid) inner core. The core may be a low molecular weight polymer, and the shell may be an inorganic solid. The capsules 370 may be similar to the capsules 270 described above with respect to FIG. 2.

The capsules 370 may be uniformly distributed throughout the matrix material of the liner 330. The capsules 370 may account for any volume percentage of the liner 330 that still allows for a compliable structure. For example, the capsules 370 may occupy up to approximately 20 percent of the volume of the liner 330, up to approximately 50 percent of the volume of the liner 330, or up to approximately 70 percent of the volume of the liner 330. Though, even higher volume percentages of the capsules 370 may be used in some embodiments.

Referring now to FIG. 3B, a cross-sectional illustration of the substrate 300 after a defect 315 is generated is shown, in accordance with an embodiment. As indicated by the vertical arrows (one pointing up and the other pointing down), stress can be induced into the structure of the substrate 300 due to CTE mismatch between the via 320 and the glass layer 301. The stress may be at least partially absorbed by the liner 330. However, some amount of stress may be transferred across the liner 330. This transferred stress can result in the formation of a defect 315.

The defect 315 in FIG. 3B is shown at the interface between the liner 330 and the glass layer 301. The defect 315 has an opening at the surface of the liner 330 and propagates towards a point within the glass layer 301. While a simple crack defect 315 is shown in FIG. 3B, it is to be appreciated that defects 315 may have any shape, size, structure, etc. Further, while a single defect 315 is shown in FIG. 3B, it is to be appreciated that multiple defects 315 may be provided within a single substrate 300.

Referring now to FIG. 3C, a cross-sectional illustration of the substrate 300 after several of the capsules 370 are cracked open is shown, in accordance with an embodiment. In an embodiment, the capsules 370 may crack through the application of pressure on the outer shells. The pressure may be supplied through the same mechanism that generates the defects 315. That is, CTE mismatch between the via 320 and the glass layer 301 may result in pressure being applied to the liner 330. Depending on the thickness and material of the outer shell of capsules 370, this pressure may result in the outer shell cracking to release the liquid core 372.

It is to be appreciated that the pressure throughout the entire liner 330 may not be uniform. This may result in some of the capsules 370 cracking, while other capsules 370 remain intact. Additionally, the capsules 370 may have non-uniform dimensions, materials, or the like. For example, outer shells can have different thicknesses or be made from different materials. This allows for capsules 370 to crack at different pressures.

The pressure applied to the liner 330 may drive the released liquid cores 372 to the defect 315, which would typically be at a lower pressure than the surrounding areas. While the liquid cores 372 are shown as maintaining their circular shape in FIG. 3C, it is to be appreciated that the cores 372 may instead flow naturally as streams or other fluidic distributions towards the defect 315.

Referring now to FIG. 3D, a cross-sectional illustration of the substrate 300 after the liquid cores 372 have filled the defect 315 is shown, in accordance with an embodiment. In an embodiment, the liquid cores 372 fill the defect 315 and are subsequently solidified to form a plug 317. The solidification can arise out of a curing process and/or a cross-linking process. The solidification process can be aided when there are solvents and/or cross-linking agents integrated as part of the liquid cores 372. The solidification process of the plug 317 can also be enhanced through the application of heat. This is particularly useful, since the process that generates the defects 315 is typically a heating process (e.g., reflow, annealing, etc.). Accordingly, there is typically sufficient thermal energy available in order to enable the solidification process to form the plugs 317. The plugs 317 will generally reduce the stress that is localized at the defect 315 within the glass layer 301. The reduction in stress, particularly at the terminal points of the defect 315, will mitigate further propagation of the defect 315 into the body of the glass layer 301.

In the embodiment shown and described with respect to FIGS. 3A-3D, the self-healing process involved the transfer of a material from the liner to the defect itself. However, embodiments are not limited to such transport mechanisms. Instead, embodiments disclosed herein may also use the material surrounding the defect in order to heal or mitigate the defect. More particularly, localized melting may be used in order to reform the material without the defect present. The localized reflowing may be implemented through the use of paramagnetic nanoparticles that are distributed in the liner.

Paramagnetic nanoparticles can be activated through the application of a magnetic field to the substrate. The magnetic field induces vibration in the nanoparticles, which in turn can be used to heat up and melt the surrounding material. The paramagnetic nanoparticles may sometimes be considered superparamagnetic nanoparticles. Such particles may be melt blended or solution mixed into a polymer matrix used to form the liner between the via and the glass layer. The nanoparticles may comprise iron and oxygen. In one instance the nanoparticles comprise at least 40 percent (by weight) iron and at least 40 percent (by weight) oxygen. For example, the nanoparticles may comprise Fe₂O₃ particles. Though, it is to be appreciated that other paramagnetic or superparamagnetic materials may also be used for the nanoparticles. The nanoparticles may also be surface-functionalized in some instances. The nanoparticles may have an average diameter that is between approximately 1 nm and approximately 500 nm. Though, smaller or larger nanoparticles may also be used in some embodiments. In some embodiments, the nanoparticles may comprise up to 5 percent (by volume) of the liner, up to 25 percent (by volume) of the liner, up to 40 percent (by volume) of the liner, or up to 80 percent (by volume) of the liner.

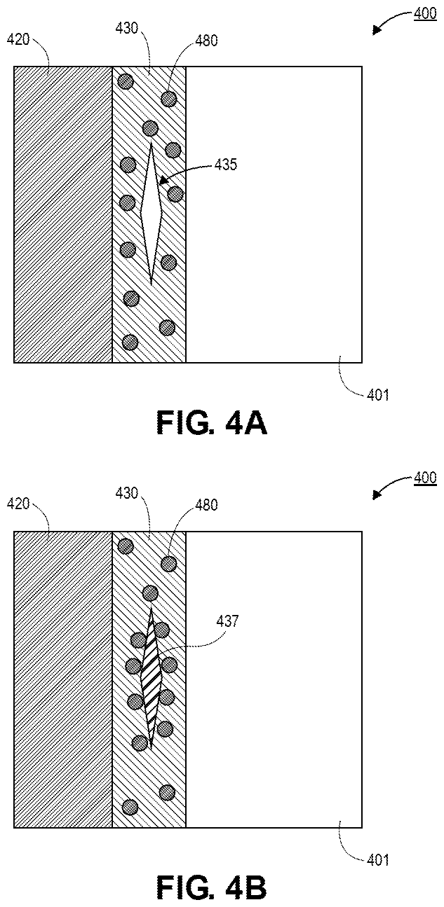

Referring now to FIGS. 4A and 4B, a pair of cross-sectional illustrations depicting a substrate 400 with a via 420 and a liner 430 is shown, in accordance with an embodiment. The liner 430 may include nanoparticles 480 similar to the nanoparticles described in greater detail above.

Referring now to FIG. 4A, a cross-sectional illustration of a substrate 400 is shown, in accordance with an embodiment. In an embodiment, the substrate 400 may comprise a glass layer 401. The glass layer 401 may have a composition and structure similar to any of those described in greater detail herein. A via 420 may be provided through a thickness of the glass layer 401, and a liner 430 may separate the via 420 from the glass layer 401. The via 420 may be an electrically conductive via 420 similar to any of the electrically conductive vias described in greater detail herein. In an embodiment, liner 430 may be a polymeric material with nanoparticles 480 distributed within the polymeric material. The nanoparticles 480 may be similar to the nanoparticles described in greater detail above. In the illustrated embodiment, only a zoomed in illustration of a single interface between the via 420, liner 430, and glass layer 401 is shown for simplicity. However, it is to be appreciated that the substrate 400 may have via 420 and liner 430 structures that are similar to those described above with respect to FIGS. 1A-1C.

In an embodiment, a defect 435 may be present within the liner 430. For example, the defect 435 in FIG. 4A may be a void. The defect 435 may be the result of a cohesion failure, delamination, or the like. The defect 435 may be attributable to the CTE mismatch between the via 420 and the glass layer 401. For example, different rates of expansion may lead to the formation of the defect 435. The defect 435 in FIG. 4A is shown as being diamond shaped. Though, it is to be appreciated that defects 435 may take any form, shape, or size. Further, while a single defect 435 is shown, embodiments may also include a plurality of defects 435 within the liner 430.

Referring now to FIG. 4B, a cross-sectional illustration of the substrate 400 after the defect 435 is mitigated is shown, in accordance with an embodiment. In an embodiment, the defect 435 may attract a sufficient number of the nanoparticles 480. For example, nanoparticles 480 may surround a perimeter of the defect 435. After nanoparticles 480 are proximate to the defect 435, a magnetic field may be applied to the substrate 400. The magnetic field 400 may induce motion in the nanoparticles 480. Due to the concentration of nanoparticles 480 around the defect 435, localized melting may occur. The liquefied polymer material may then reflow and fill the defect 435. As shown in FIG. 4B, a reflown zone 437 has a different shading than the rest of the liner 430. However, in some instances, there may not be a discernable boundary between the reflown region and the remainder of the liner 430. That is, the previous defect 435 may be substantially undetectable.

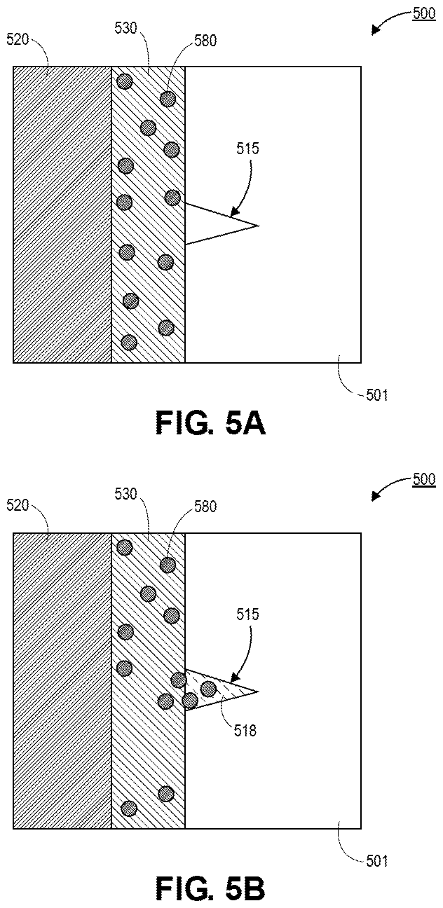

Referring now to FIGS. 5A-5B, a pair of cross-sectional illustrations depicting a self-healing mechanism similar to the one shown in FIGS. 4A and 4B is provided. However, in FIGS. 5A and 5B, the defect is provided in the glass layer adjacent to the liner.

Referring now to FIG. 5A, a cross-sectional illustration of a substrate 500 is shown, in accordance with an embodiment. In an embodiment, the substrate 500 may comprise a glass layer 501. The glass layer 501 may have a composition and structure similar to any of those described in greater detail herein. A via 520 may be provided through a thickness of the glass layer 501, and a liner 530 may separate the via 520 from the glass layer 501. The via 520 may be an electrically conductive via 520 similar to any of the electrically conductive vias described in greater detail herein. In an embodiment, liner 530 may be a polymeric material with nanoparticles 580 distributed within the polymeric material. The nanoparticles 580 may be similar to the nanoparticles described in greater detail above. In the illustrated embodiment, only a zoomed in illustration of a single interface between the via 520, liner 530, and glass layer 501 is shown for simplicity. However, it is to be appreciated that the substrate 500 may have via 520 and liner 530 structures that are similar to those described above with respect to FIGS. 1A-1C.

In an embodiment, a defect 515 may be located in the glass layer 501 at the interface between the glass layer 501 and the liner 530. The defect 515 may be attributable to the CTE mismatch between the via 520 and the glass layer 501. For example, different rates of expansion may lead to the formation of the defect 515. In the illustrated embodiment, the defect 515 is a simple crack that has an opening facing the liner 530 and which comes to a point within the glass layer 501. Though, it is to be appreciated that defect 515 may take any form, shape, or size. Further, while a single defect 515 is shown, embodiments may also include a plurality of defects 515 within the glass layer 501.

Referring now to FIG. 5B, a cross-sectional illustration of the substrate 500 after the defect 515 is mitigated is shown, in accordance with an embodiment. In an embodiment, the defect 515 may be mitigated through use of the nanoparticles 580. For example, the nanoparticles may conglomerate around the defect 515. A magnetic field may then be applied in order to induce rapid motion of the nanoparticles 580 in order to induce localized melting of the materials surrounding the nanoparticles 580. In some instances, the melting includes melting the glass material of the glass layer 501. In such instances the fill 518 may be solidified glass. Though, in other embodiments, portions of the liner 530 may melt and fill the defect 515. In other embodiments, the fill 518 may include both glass and polymer.

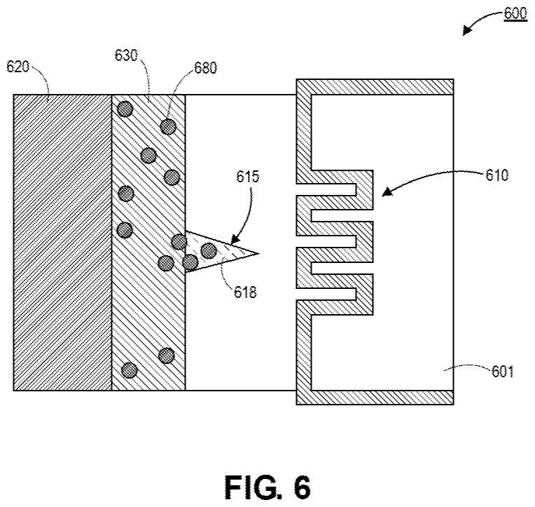

In the embodiments above with respect to FIGS. 4A, 4B, 5A, and 5B, the nanoparticles are described as being activated through the application of a magnetic field into the substrate 400 or 500. The magnetic field may be an external magnetic field that is applied to the substrate 400 or 500 (e.g., by bringing a magnetic into the proximity of the substrate). In other embodiments, the magnetic field may be internally applied. An example of such an embodiment is shown in FIG. 6.

Referring now to FIG. 6, a cross-sectional illustration of a substrate 600 is shown, in accordance with an embodiment. In an embodiment, the substrate 600 may include a glass layer 601, a via 620, and a liner 630. The liner 630 may have paramagnetic nanoparticles 680 distributed within a polymer matrix. Additionally, a defect 615 may be present at the interface between the liner 630 and the glass layer 601. The defect 615 may be a crack, a void, or any other type of defect. In the illustrated embodiment, the defect 615 has been mitigated by a fill 618 that is obtained through the use of localized melting induced by rapid motion of the nanoparticles 680.

However, instead of relying on an external magnetic field, an internal magnetic field is supplied. Such an internal magnetic field may be generated through the use of an electrically conductive coil 610 or the like. In the illustrated embodiment, the conductive coil 610 is provided through the glass layer 601. In other embodiments, a conductive coil 610 may be provided above and/or below the glass layer 601. Accordingly, when repair is needed to mitigate or fix a defect 615, current can be passed through the conductive coil 610 in order to induce a magnetic field in the substrate 600.

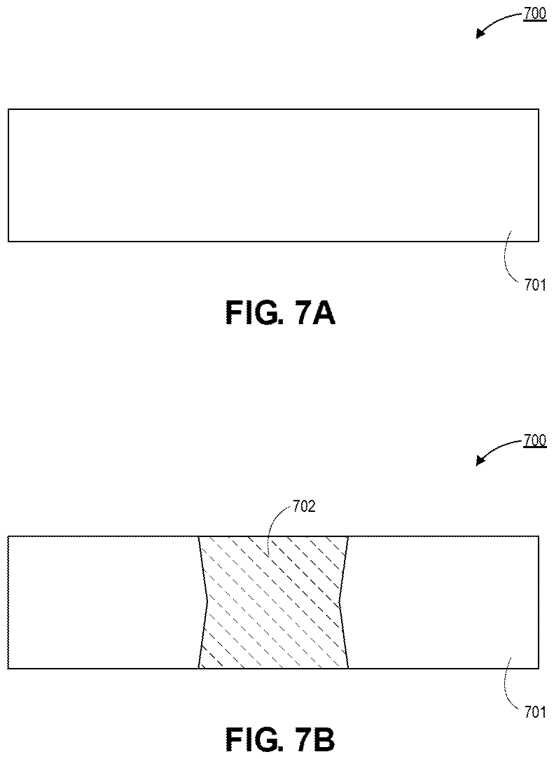

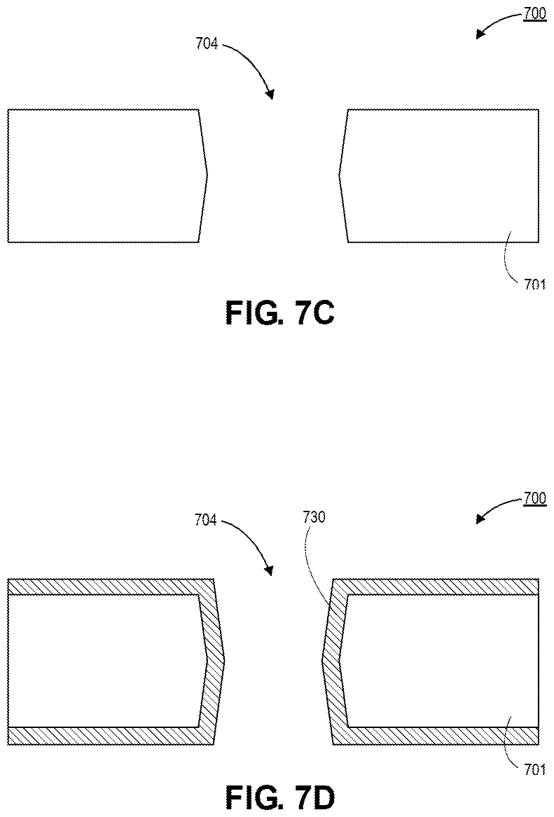

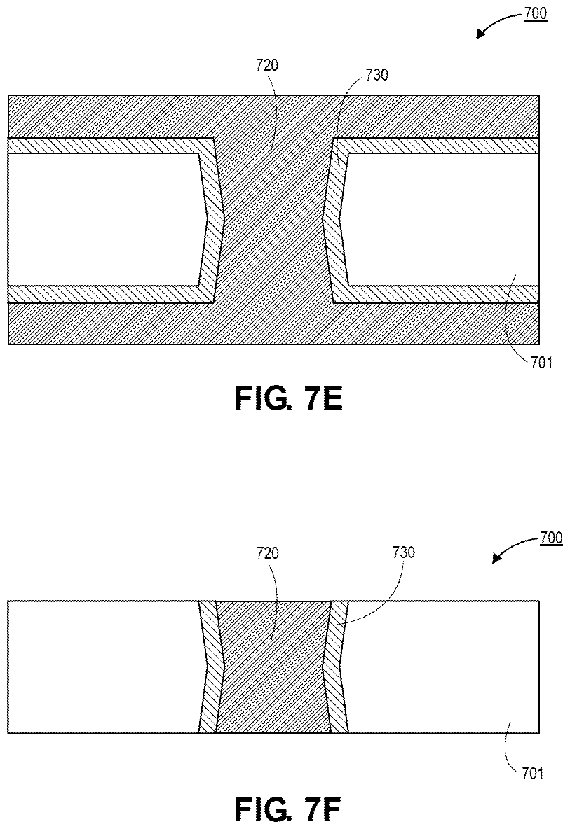

Referring now to FIGS. 7A-7F, a series of cross-sectional illustrations depicting a process for forming a substrate 700 with a liner 730 capable of self-healing functionality is shown, in accordance with an embodiment.

Referring now to FIG. 7A, a cross-sectional illustration of a substrate 700 is shown, in accordance with an embodiment. In an embodiment, the substrate 700 comprises a glass layer 701. The glass layer 701 may have a composition and structure similar to any of the glass layers described in greater detail herein. The substrate 700 may be used as a core for a package substrate, as an interposer, or as any other type of substrate that can benefit from self-healing liners.

Referring now to FIG. 7B, a cross-sectional illustration of the substrate 700 after the glass layer 701 is exposed to a laser treatment is shown, in accordance with an embodiment. The laser treatment modifies the glass layer 701 in order to form a modified glass region 702. The modified glass region 702 may be more susceptible to an etching process used to form the via opening in the subsequent processing operation.

Referring now to FIG. 7C, a cross-sectional illustration of the substrate 700 after the modified glass region 702 is removed to form a via opening 704 is shown, in accordance with an embodiment. The via opening 704 may pass through a thickness of the glass layer 701. Sidewalls of the via opening 704 may be tapered. In the illustrated embodiment, the via opening 704 has double tapered sidewalls in order to form an hourglass shaped via opening 704. Though other embodiments may include a via opening 704 with a single taper or with substantially vertical sidewalls. Different profiles of the via opening 704 may be dependent on the type of patterning used to form the via opening 704.

Referring now to FIG. 7D, a cross-sectional illustration of the substrate 700 after a liner 730 is added is shown, in accordance with an embodiment. The liner 730 may be applied with any suitable coating process, such as, but not limited to, chemical vapor deposition (CVD), physical vapor deposition (PVD), atomic layer deposition (ALD), and the like. The liner 730 may have a polymer matrix that is filled with particles (not shown) suitable for implementing a self-healing process. For example, the particles may include capsules with a solid outer shell and a liquid organic core. Other embodiments may include particles that are paramagnetic nanoparticles or superparamagnetic nanoparticles.

Referring now to FIG. 7E, a cross-sectional illustration of the substrate 700 after the via 720 is added is shown, in accordance with an embodiment. In an embodiment, the via 720 may be formed with a plating process, such as an electroplating process. In such an embodiment, a seed layer (not shown) may be deposited first with an electroless plating process or any other suitable deposition process. The via 720 may fill the remainder of the via opening 704.

Referring now to FIG. 7F, a cross-sectional illustration of the substrate 700 after any overburden is removed is shown, in accordance with an embodiment. In an embodiment, the overburden may be removed from the top and bottom surfaces of the glass layer 701. For example, a polishing process, such as a chemical mechanical polishing (CMP) process, an etching process, or the like may be used to remove excess portions of the liner 730 and the via 720. After the polishing, standard buildup processes may be used in order to form organic buildup layers above and/or below the substrate 700.

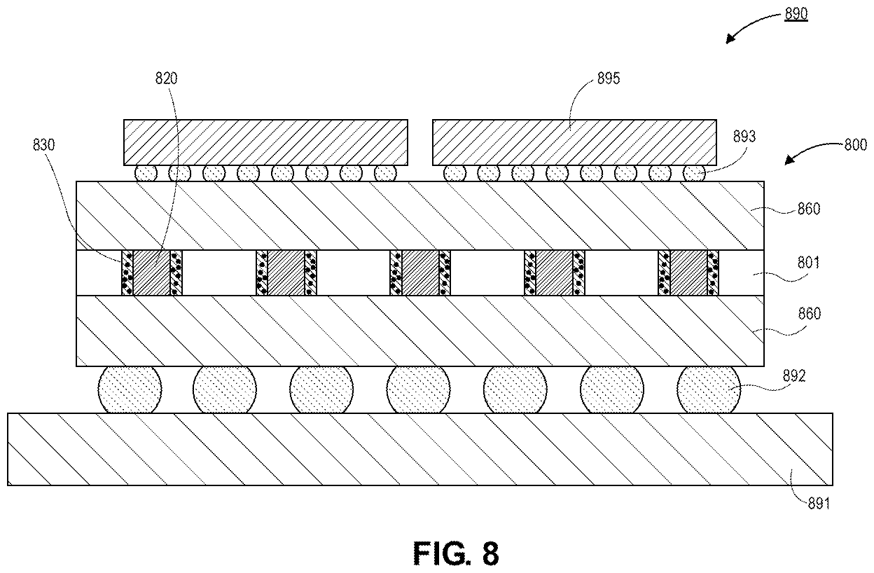

Referring now to FIG. 8, a cross-sectional illustration of an electronic system 890 is shown, in accordance with an embodiment. In an embodiment, the electronic system 890 may comprise a board 891, such as a printed circuit board (PCB). The board 891 may be coupled to a package substrate 800 by interconnects 892. The interconnects 892 may be any suitable second level interconnect (SLI) architecture, such as solder balls, pins, or the like.

In an embodiment, the package substrate 800 may comprise a glass core 801 with organic buildup layers 860 above and/or below the glass core 801. The glass core 801 may have through glass vias (TGVs) 820. The TGVs 820 may be separated from the glass core 801 by a liner 830. The liner 830 may have filler particles suitable for implementing self-healing processes, such as those described in greater detail above. For example, the filler particles may be capsules with a shell and liquid core, or the filler particles may be superparamagnetic nanoparticles.

In an embodiment, the package substrate 800 may be coupled to one or more dies 895 by interconnects 893. The interconnects 893 may be any suitable first level interconnect (FLI) architecture, such as solder balls, copper bumps, hybrid bonding interfaces, or the like. In an embodiment, the dies 895 may comprise compute dies such as a central processing unit (CPU), a graphics processing unit (GPU), an XPU, a communications die, or the like. Dies 895 may also include memory dies or any other type of die that is beneficial for the electronic system 890.

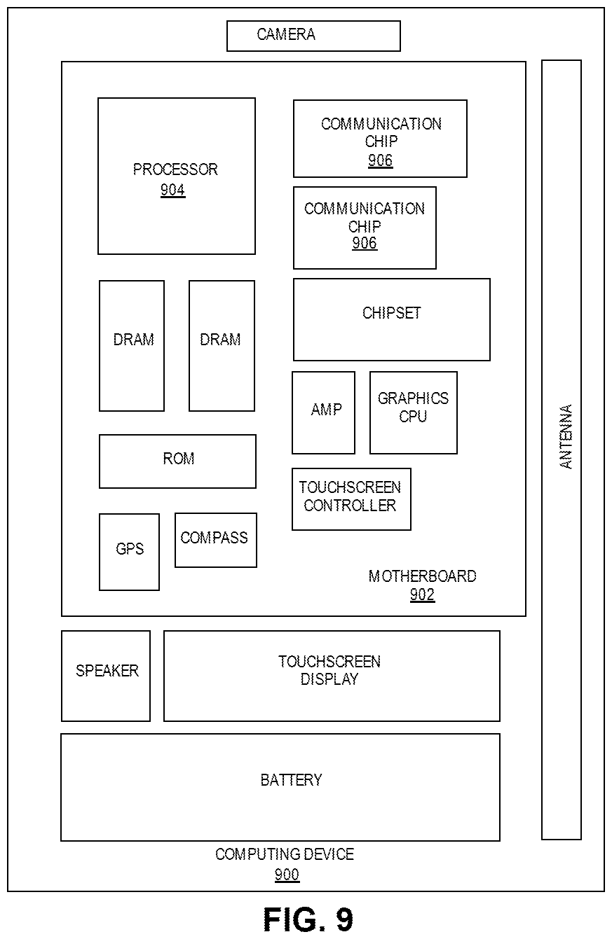

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor may be part of an electronic package that includes a package substrate with a glass core that includes a liner around vias, where the liner includes particles for self-healing applications, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the disclosure, the integrated circuit die of the communication chip may be part of an electronic package that includes a package substrate with a glass core that includes a liner around vias, where the liner includes particles for self-healing applications, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate, wherein the substrate comprises a solid glass layer; an opening through a thickness of the substrate; a liner in contact with a sidewall of the opening, wherein the liner comprises a polymer matrix with capsules distributed through the polymer matrix, wherein at least one of the capsules comprises: a shell; and a core within the shell, wherein the core comprises an organic material; and a via in the opening and in contact with the liner, wherein the via is electrically conductive.

Example 2: the apparatus of Example 1, wherein the shell comprises an inorganic material.

Example 3: the apparatus of Example 2, wherein the shell comprises silicon and oxygen.

Example 4: the apparatus of Examples 1-3, wherein the core comprises a polymer and one or both of a solvent and a cross-linking agent.

Example 5: the apparatus of Examples 1-4, wherein the core is a liquid.

Example 6: the apparatus of Examples 1-5, wherein the liner has a thickness that is between approximately 10 nm and approximately 100 nm.

Example 7: the apparatus of Examples 1-6, wherein a volume percentage of the capsules in the liner is up to approximately 50 percent.

Example 8: the apparatus of Examples 1-7, further comprising: a crack in the substrate adjacent to the liner, and wherein the crack contains a material with the same organic composition as the core material.

Example 9: the apparatus of Example 8, wherein the organic material of the cores in the crack is solid.

Example 10: an apparatus, comprising: a substrate, wherein the substrate comprises a solid glass layer; an opening through a thickness of the substrate; a liner in contact with a sidewall of the opening, wherein the liner comprises: a polymer matrix; and nanoparticles distributed in the polymer matrix, wherein the nanoparticles are paramagnetic; and a via in the opening, wherein the via is electrically conductive.

Example 11: the apparatus of Example 10, wherein the nanoparticles comprise iron and oxygen.

Example 12: the apparatus of Example 11, wherein the nanoparticles comprise at least 40 percent by weight iron and at least 40 percent by weight oxygen.

Example 13: the apparatus of Examples 10-12, wherein the nanoparticles are surface functionalized.

Example 14: the apparatus of Examples 10-13, wherein the nanoparticles have an average diameter that is approximately 100 nm or smaller.

Example 15: the apparatus of Examples 10-14, wherein the liner has a thickness between approximately 1 μm and approximately 30 μm.

Example 16: the apparatus of Examples 10-15, wherein nanoparticles comprise up to 40 percent by volume of the liner.

Example 17: an apparatus, comprising: a board; a package substrate over the board, wherein the package substrate comprises: a core, wherein the core is solid glass; a via through the core, wherein the via is electrically conductive; a liner between the via and the core, wherein the liner comprises: a matrix; and particles distributed within the matrix; and a die coupled to the package substrate.

Example 18: the apparatus of Example 17, wherein the particles are capsules with an inorganic shell and a liquid organic core.

Example 19: the apparatus of Example 17, wherein the particles are paramagnetic nanoparticles.

Example 20: the apparatus of Examples 17-19, wherein the apparatus is part of a personal computer, a server, a mobile device, a tablet, or an automobile.

What is claimed is:

1. An apparatus, comprising:
a substrate, wherein the substrate comprises a solid glass layer;
an opening through a thickness of the substrate;
a liner in contact with a sidewall of the opening, wherein the liner comprises a polymer matrix with capsules distributed through the polymer matrix, wherein at least one of the capsules comprises:
a shell; and
a core within the shell, wherein the core comprises an organic material; and
a via in the opening and in contact with the liner, wherein the via is electrically conductive.

2. The apparatus of claim 1, wherein the shell comprises an inorganic material.

3. The apparatus of claim 2, wherein the shell comprises silicon and oxygen.

4. The apparatus of claim 1, wherein the core comprises a polymer and one or both of a solvent and a cross-linking agent.

5. The apparatus of claim 1, wherein the core is a liquid.

6. The apparatus of claim 1, wherein the liner has a thickness that is between approximately 10 nm and approximately 100 nm.

7. The apparatus of claim 1, wherein a volume percentage of the capsules in the liner is up to approximately 50 percent.

8. The apparatus of claim 1, further comprising:
a crack in the substrate adjacent to the liner, and wherein the crack contains a material with the same organic composition as the core material.

9. The apparatus of claim 8, wherein the organic material of the cores in the crack is solid.

10. An apparatus, comprising:
a substrate, wherein the substrate comprises a solid glass layer;
an opening through a thickness of the substrate;
a liner in contact with a sidewall of the opening, wherein the liner comprises:
a polymer matrix; and
nanoparticles distributed in the polymer matrix, wherein the nanoparticles are paramagnetic; and
a via in the opening, wherein the via is electrically conductive.

11. The apparatus of claim 10, wherein the nanoparticles comprise iron and oxygen.

12. The apparatus of claim 11, wherein the nanoparticles comprise at least 40 percent by weight iron and at least 40 percent by weight oxygen.

13. The apparatus of claim 10, wherein the nanoparticles are surface functionalized.

14. The apparatus of claim 10, wherein the nanoparticles have an average diameter that is approximately 100 nm or smaller.

15. The apparatus of claim 10, wherein the liner has a thickness between approximately 1 μm and approximately 30 μm.

16. The apparatus of claim 10, wherein nanoparticles comprise up to 40 percent by volume of the liner.

17. An apparatus, comprising:
a board;
a package substrate over the board, wherein the package substrate comprises:
a core, wherein the core is solid glass;
a via through the core, wherein the via is electrically conductive;
a liner between the via and the core, wherein the liner comprises:
a matrix; and
particles distributed within the matrix; and
a die coupled to the package substrate.

18. The apparatus of claim 17, wherein the particles are capsules with an inorganic shell and a liquid organic core.

19. The apparatus of claim 17, wherein the particles are paramagnetic nanoparticles.

20. The apparatus of claim 17, wherein the apparatus is part of a personal computer, a server, a mobile device, a tablet, or an automobile.
